(19) United States
(12) Patent Application Publication
(10) Pub. No.: US 2022/0399180 A1
(43) Pub. Date: Dec. 15, 2022

(54) Sample Delivery, Data Acquisition, and Analysis, and Automation Thereof, in Charged-Particle-Beam Microscopy

(71) Applicant: Mochii, Inc. (d/b/a Voxa), Seattle, WA (US)

(72) Inventor: Christopher Su-Yan Own, Seattle, WA (US)

(21) Appl. No.: 17/841,657

(22) Filed: Jun. 15, 2022

Related U.S. Application Data
(60) Provisional application No. 63/210,983, filed on Jun. 15, 2021.

(51) Int. Cl. H01J 37/28; H01J 37/20; H01J 37/244; H01J 37/26; H01J 37/22

(52) U.S. Cl. CPC H01J 37/28; H01J 37/20; H01J 37/244; H01J 37/265; H01J 37/222; H01J 2237/2802

(57) ABSTRACT

A charged-particle-beam microscope for imaging a sample, the microscope having a stage to hold a sample and an automated sample feeder to repeatedly and automatically exchange the sample from among a plurality of samples. A charged-particle-beam column is provided to direct a charged-particle-beam onto the sample, the charged-particle-beam column. The column includes a charged-particle-beam source to generate an electron beam and charged-particle-beam optics to converge the charged-particle beam onto the sample. A detector is provided to detect charged particles emanating from the sample to generate image data. A controller executes an artificial intelligence algorithm to analyze the image data.

### CLAIM FOR PRIORITY

This application claims priority under 35 U.S.C. § 119(e) to Provisional Application 63/210,983, filed Jun. 15, 2021, which is incorporated herein by reference in its entirety.

### TECHNICAL FIELD

This application relates to sample delivery, data acquisition, and analysis, and automation thereof, in charged-particle-beam microscopy.

### BACKGROUND

Charged-particle beam microscope systems may be used to observe one or more samples at very small dimensions. For example, a transmission electron microscope (TEM), scanning electron microscope (SEM), scanning transmission electron microscope (STEM), or focused ion beam (FIB) microscope may be adapted and used advantageously to image and analyze samples at the nanometer scale.

However, conventional charged-particle beam microscopes typically have a number of practical disadvantages in terms of speed and cost. Imaging numerous samples by conventional means may be slow and expensive. For example, sequential imaging of multiple samples may require frequent pumping cycles and recurring human manual intervention to insert samples. As another example, transmission electron microscopy (TEM) may require frequent and slow stage movements in order to image a large area of a sample or an entire sample, making it slow and therefore expensive to image large areas. Moreover, when imaging numerous samples, it may be difficult and labor-intensive to track the identity of each sample in relation to its digital image.

Thus, it is desirable to provide charged-particle beam microscopy that can image numerous samples at relatively high speed and low cost. It is also desirable to be able to reliably and efficiently track the identities of each of multiple samples that are being imaged through charged-particle beam microscopy.

### SUMMARY

In one embodiment, a charged-particle-beam microscope for imaging a sample is provided. The microscope comprises a stage to hold a sample and an automated sample feeder to repeatedly and automatically exchange the sample from among a plurality of samples. A charged-particle-beam column is provided to direct a charged-particle-beam onto the sample. The charged-particle-beam column comprises a charged-particle-beam source to generate an electron beam, and charged-particle-beam optics to converge the charged-particle beam onto the sample. A detector is provided to detect charged particles emanating from the sample to generate image data. A controller is provided to analyze the image data to generate an image, the controller being adapted to execute an artificial intelligence algorithm to analyze the image.

It is to be understood that both the foregoing general description and the following detailed description are exemplary and explanatory only and are not restrictive of the invention as claimed.

### BRIEF DESCRIPTION OF THE DRAWINGS

The accompanying drawings, which are incorporated in and constitute a part of this specification, illustrate several embodiments and aspects of the transmission electron microscopes described herein and, together with the description, serve to explain the principles of the invention.

FIG. 1 is a schematic diagram is a schematic diagram of an exemplary embodiment of a TEM column with a beam scanner.

FIGS. 2, 3, 4, 5, and 6 are schematic diagrams of top views of fields of view of a TEM on a sample area of interest.

FIG. 7 is a is a schematic timeline of an example of a comparison between how time is used in a conventional stage-only rastering and how time is used in combination stage-beam rastering.

FIGS. 8A and 8B are grayscale illustrations of an example of an embodiment of scanning a nine-field supertile by an electron beam as part of combination stage-beam rastering of a cortical tissue section sample.

FIG. 9 is a schematic diagram of an example of an embodiment of a grid stick, a chip stick, an airlock, and a magazine.

FIG. 10 illustrates cross-sectional and top perspective views, respectively, of six examples of different embodiments of grid sticks.

FIG. 11A is a perspective view of another exemplary embodiment of a grid stick.

FIG. 11B is a perspective view of another exemplary embodiment of a chip stick.

FIG. 11C illustrates cross-sectional and top perspective views of a chip stick that can take the place of the sample clamp while a specially patterned mechanical carrier of the chip stick also acts as the sample supports.

FIG. 12 is a perspective view of a sample tray of an example of an embodiment of a grid stick that has a one-dimensional array of apertures.

FIG. 13A is a schematic illustration of an example of an embodiment of a magazine being split at the location of a randomly-accessed grid stick or chip stick and a mechanism that accesses the addressed grid stick or chip stick.

FIG. 13B is a schematic illustration of an example of an embodiment of a magazine serving grid sticks or chip sticks sequentially.

FIG. 14 illustrates a schematic side view of an example of an embodiment of a charged-particle beam microscope having an airlock that permits cartridges to be inserted into the vacuum chamber and to move samples in the observation area.

FIG. 15 illustrates a perspective view of an example of an embodiment of a cartridge holding a sample stick with a carrier and a sample on the carrier.

FIG. 16 is a schematic diagram of an example of an embodiment of an automated sample feeder that includes a grid tape loader (GTL).

FIGS. 17A, 17B, 17C, and 17D are three-dimensional rendered perspective views of stages of an example of an embodiment of loading a reel of sample tape into the grid tape loader of FIG. 16.

FIG. 18 is a schematic diagram of communications between microscope hardware, a controller, and multiple clients.

FIG. 19 is an example of an embodiment of a workflow in an automated sample preparation, delivery, charged-particle-beam imaging, and analysis pipeline.

### DETAILED DESCRIPTION

A charged-particle beam microscope—such as a transmission electron microscope (TEM), scanning electron microscope (SEM), scanning transmission electron microscope (STEM), or focused ion beam (FIB) microscope—may be adapted and used advantageously to image and analyze samples. The microscope may illuminate the sample with one or more charged-particle beams (such as electron beams) and detect radiation from the sample to generate an image of the sample. A TEM, for example, converges an electron beam into a “field of view” on the sample to image that field. A SEM or STEM, meanwhile, scans an electron beam that is formed into a probe across the sample to generate an image pixel-by-pixel. The images may be evaluated, such as by a human user of the microscope or automatically, to identify characteristics of the sample.

Examples of microscopy apparatuses are described in, for example, U.S. patent application Ser. No. 16/355,704 to Christopher S. Own, filed Mar. 15, 2019, and U.S. Patent Appl. Pub. No. 2019/0287759 to Christopher S. Own et al., titled “Transmission Electron Microscopy” and published Sep. 19, 2019, which are incorporated herein by reference in their entireties.

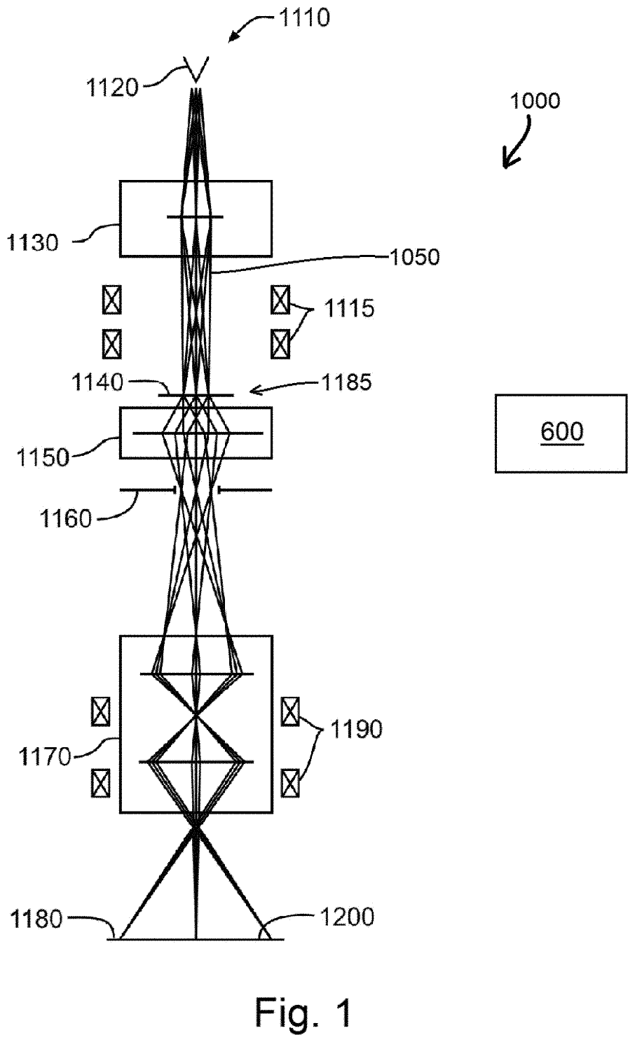

FIG. 1 is a schematic diagram of an example of an embodiment of a charged-particle-beam microscope 1000 that is a TEM. Micrsoscope 1000 comprises a TEM column 1110 with a beam scanner 1115 and a beam descanner 1190. Column 1110 has an electron source 1120, one or more condenser lenses 1130, beam scanner 1115, optionally sample 1140 to be imaged, objective lens 1150, annular aperture 1160, one or more projecting lenses 1170, beam descanner 1190, and detector 1180. Image plane 1200 is shown in the figure. Electron source 1120 and condenser lenses 1130 are configured to provide a variety of illumination conditions. Beam scanner 1115 and beam descanner 1190 are adapted to scan (including discretely shifting) a substantially parallel electron beam across the sample (i.e., sample 1140). The charged-particle-beam microscope may comprise a stage (e.g., stage 1185) to move the sample (i.e., sample 1140) in one or more degrees of freedom, which may include tilting the sample. The charged-particle beam microscope 10 may also include a controller (e.g., controller 600) to control the operation of the microscope.

The microscope may include or be connected to a power supply that provides power to components of the microscope. The power supply may include one or more individual power supplies, such as set to different voltages or otherwise taking different forms. Components of a charged-particle beam microscope that receive power from the power supply may, for example, include a charged-particle beam source (e.g., electron beam 1120), condenser lenses (e.g., condenser lenses 1130), the objective lens (e.g., objective lens 1150), the detectors (e.g., detector 1180), and the stage (e.g., stage 1185). The power supply also provides power to the pumps of microscope 10, and to any other components of microscope 10 that consume power. In one embodiment of a charged-particle beam microscope, the optical system of microscope 10 has a total power consumption for all such components of less than about 2.5 kW. In another embodiment, designed for power efficiency, microscope 10 is a charged-particle beam microscope that has a total power consumption of less than about 1 kW. In yet another embodiment optimized for very high efficiency, microscope 10 is a charged-particle beam microscope that has a total power consumption of less than about 100 W.

In a charged-particle-beam microscope, the power supply can provide one or more voltages to accelerate the charged-particle beam. In one version, the power supply includes at least one high-voltage supply, which may be used for a number of lenses. A single high-voltage supply that may be used to provide the primary beam energy can be modified with resistors to provide multiple values to different lenses that are at a ratio of the primary high-voltage value of the high-voltage supply. These resistors may be either constant or programmable by the controller. In this manner, instabilities that may be present in the high voltage signal can be provided substantially equally to the multiple lenses and the effects of the instabilities can be lessened. The power supply may also include one or more low-voltage supplies, such as to provide lower voltages to nonround lenses, such as dipoles, quadrupoles, and octupoles.

The stage of the charged-particle beam microscope may comprise a cartridge to support and precisely move one or more samples in the observation area. Cartridge may contain one or more actuators, such as motors, that are disposed inside or nearer the imaging area (e.g., within the vacuum chamber) than with conventional sample stages. In one version, cartridge is adapted to hold a sample stick that supports one or more samples inside the apparatus for imaging. Some examples of embodiments of such a “cartridge” are described in U.S. patent application Ser. No. 16/355,704 to Christopher S. Own, and U.S. Patent Appl. Pub. No. 2019/0287759 to Christopher S. Own et al.

In one version, the microscope is a TEM that controls one or more of the beam scanners (e.g., beam scanner 1115 and beam descanner 1190) and the stage (e.g., stage 1185) for combination stage-beam rastering within, and between, “supertiles.” This TEM may be configured to shift the field of view of the charged-particle beam across a sample one or more times between consecutive stage movements. Between stage movements, the beam scanners may generate a magnetic and/or electric field to scan the electron beam from field to field. When all fields of view within a “supertile” have been imaged, the stage is moved to image the next “supertile.” Such combination stage-beam rastering across “supertiles” may allow the acquisition and analysis of large areas of samples to be performed quickly and reliably as compared to a conventional stage-only rastering TEM.

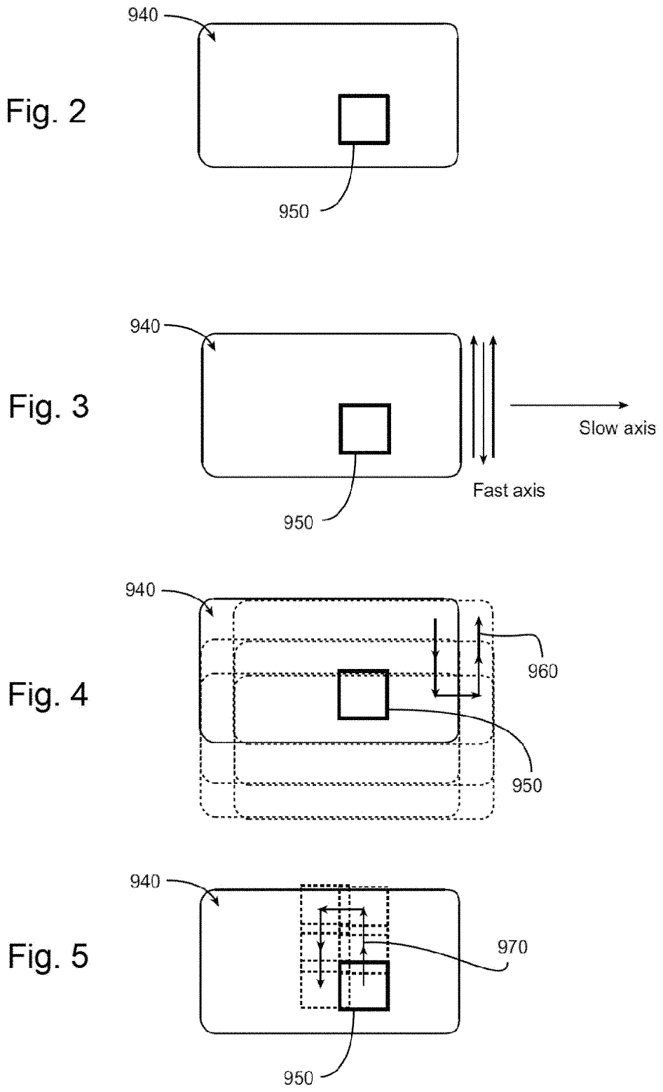

FIG. 2 is a schematic top view showing an example of an area 940 of a sample that is desired to be imaged as well as a field of view 950 of a TEM. As shown, field of view 950 may be a fraction of sample area 940. The field of view of a TEM is typically limited by the parameters of desired magnification of the image, physical detector size, and detector pixel array size. Together these parameters constrict the maximum field of view and also the ultimate resolution of the image acquired from the detector, despite the fact that the optical system may be able to form an image larger than this field of view at full microscope resolution. This field of view limits the maximum acquisition rate and increases the amount of required overlap pixels (which are subsequently discarded after being used for tile registration) for tiled acquisition of extremely large sample areas. In one example, for the sake of illustration, the field of view may have a width or diameter of about 16 μm.

FIG. 3 is a schematic top view of an example of same sample area 940 and field of view 950, showing how field of view 950 can be shifted relative to sample area 940 by movement of the stage that holds the sample. FIG. 4 is a schematic top view showing an example of a step path 960 of the sample that is traversed by five consecutive displacements of the stage holding the sample in relation to the electron beam. In raster scanning, one scanning axis may be referred to as the “fast” axis while an orthogonal axis is referred to as the “slow” axis. For example, a shift along the “slow” axis may be performed only after all shifts have been performed in a raster line along the “fast” axis. In the example shown, the controller moves the stage two times downward along the fast axis, one time rightward along the slow axis, and then two times upward along the fast axis.

FIG. 5 is a schematic top view of an example of same sample area 940 and field of view 950, showing how field of view 950 may alternatively be shifted relative to sample area 940 by scanning the electron beam along a step path 970 without stage movement. In this example, the controller shifts the electron beam two times upward along the fast axis, one time leftward along the slow axis, and then two times downward along the fast axis.

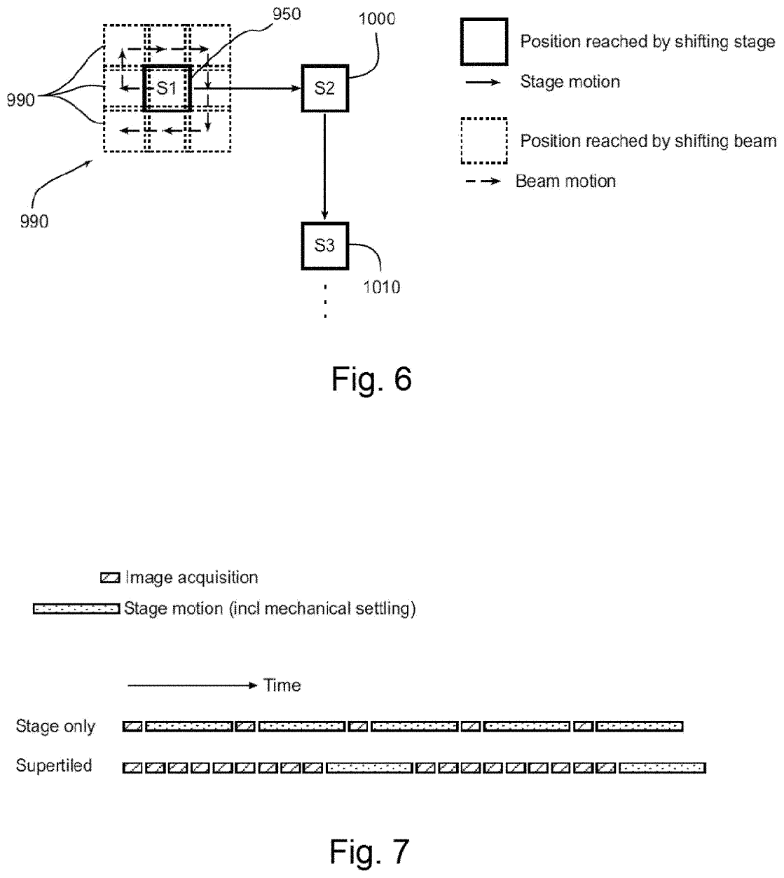

FIG. 6 is a schematic top view of an example of a field of view 950 and neighboring fields of view 980 within different fields of view, which are within range of beam scanning without stage movement. All of these nine fields of view 950, 980 may be collectively referred to as a “supertile” 990. In the example shown, the electron beam is initially positioned at central field of view 950. Next, the electron beam is shifted leftward to another field of view 980. Then, the electron beam is shifted in a clockwise pattern to each in a sequence of subsequent fields of view 980. In this example, after supertile 990 has been imaged, movement to the central field of view 1000 in a next supertile is accomplished by stage movement. And this repeats for yet another supertile 1010, and so on. Along each axis, the number of mechanical stage motions is reduced by a factor that is the number of supertile sub-images acquired along that axis; correspondingly the total number of mechanical stage motions is reduced by the square of the supertile sub-image count in the case of square supertiles.

FIG. 7 is an illustration of timelines of an example of a comparison between how time is used in a conventional stage-only rastering and how time is used in combination stage-beam rastering. The time for stage movement may include not just the rough displacement of the stage itself but additionally the time for positional settling of the stage after each movement. As shown in this figure, “supertiling” through stage-beam rastering can provide several consecutive imaging cycles (of different sub-images) between stage movements, resulting in significantly faster imaging than through stage-only rastering.

The reduction in time to set up for imaging and substantial elimination of delay between shifts across consecutive fields of view, through beam scanning rather than stage movement, may result in per-pixel acquisition that is one or more orders of magnitude faster than in a conventional TEM. In one embodiment, for example, a microscope that has an automated combination stage-beam rastering configuration may be able to acquire images at data rates at least four orders of magnitude faster than conventional instruments. For example, imaging may be performed by a microscope column faster than about 0.1 Mpixel/s (megapixels per second).

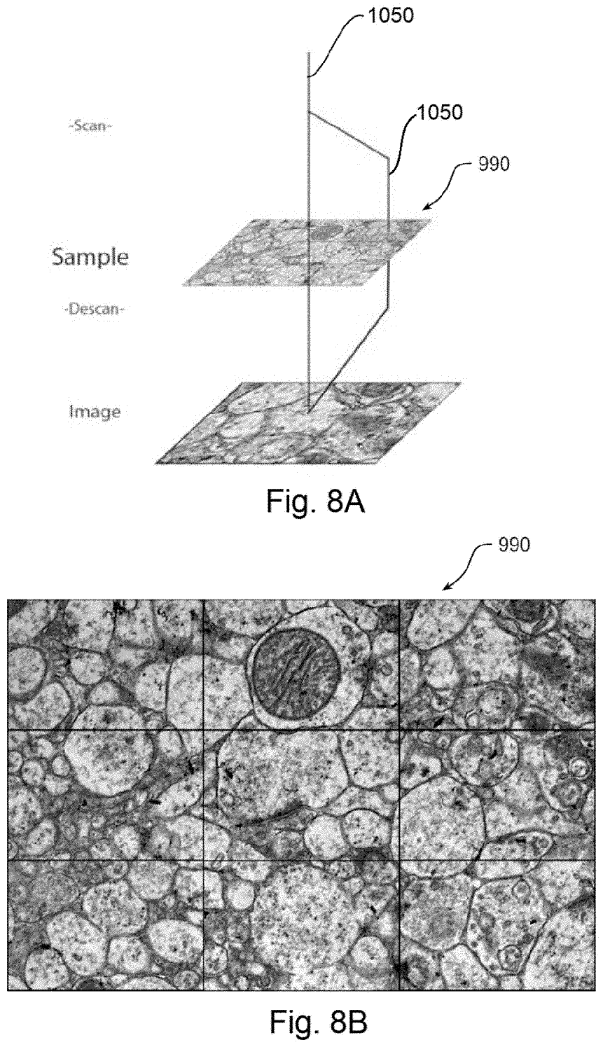

FIG. 8A is an illustration of an example of scanning of a nine-field supertile 990 by electron beam 1050 as part of combination stage-beam rastering. Electron beam 1050 is sequentially scanned to each of the nine fields of view, where the field of a cortical tissue section is imaged. FIG. 8B shows the imaged nine-field supertile 990 of cortical tissue section that is obtained at a single stage position.

In the example described above, the supertile contains nine fields of view. However, other embodiments are possible. For example, a supertile could encompass four fields of view, wherein the electron beam is scanned clockwise, counterclockwise, or in another pattern from one field of view to the next within the supertile.

In a TEM or a scanning microscope (e.g., STEM or SEM), the precise scan paths may be defined according to the particular application. For example, the location of the beam probe or field of view can be set to any position, for any time duration, along the scan path.

In one version, as a new image is being acquired, the controller aligns or otherwise conforms the new image to one or more previously generated images. For example, the controller may process newly detected pixel data to decide on or alter future imaging locations, such as to fill in gaps in imaging or to try to align the new image vertically or horizontally with one or more of the previously generated images. In another example, the controller processes newly detected pixel data to decide on or alter future image resolution or time spent at a particular location. For example, the controller may estimate a likely significance of the image at a predetermined location, and the controller may use that estimate to increase or decrease resolution or another image quality parameter for imaging at that location or nearby. These adjustments can alternatively or additionally be calculated between imaging cycles to affect the next new cycle of image acquisition.

In one embodiment, the controller controls the stage and/or beam scanners to move the beam or probe relative to the sample in a stochastic, path-dependent, or self-correcting fashion. This may be especially advantageous for electron beam microscopy due to the relatively fast response time of the electron beam to the scanning signal. For example, the controller may start creating an image by shifting the electron beam a small amount using a selected one of the beam scanners. The controller may then measure the magnitude of the shift actually produced, and use that measurement to change the amount and direction of the next shift. After more shifts and measurements have been performed, the controller may learn the strength, direction, and repeatability of the beam scanners and/or the stage. The controller may then use this learned information to produce substantially orthogonal or otherwise intentionally directed shifts at a suitable distance for stitching a larger image together. Furthermore, the controller may use the early images, although not acquired using optimal shifts, to prepare the stitched images, such that the time spent characterizing the shifts is not wasted.

Although performing these steps while images are acquired live is possible and may be a preferred operating mode, the analysis may also be performed off-line. Although it may not be possible to optimize shifts for the previously acquired image after it has occurred, that image may provide useful information for future image acquisitions, or may provide more complete information about a sample or operating instabilities when processed altogether, or may further provide information about time dependent events in a sample, such as how a sample evolves in time in a reactive environment.

As another example, as an image is tiled, areas of low or zero contrast may be identified. When images from that region are next imaged, the imaging system could spend less time on that area, or measure it at a lower resolution. This could be done at a faster rate than when acquiring normal quality images and lead to a speed up in total image acquisition time, while not affecting the quality of the image in the important areas. Lower quality images can be checked to insure that they really do represent a low-interest region, and if it is determined they do not, the image could be reacquired at higher or regular resolution.

The controller may also be adapted to increase the quality of the image at or near a feature of interest, and decrease the quality of the image (while increasing imaging speed) with increasing distance from that feature of interest.

The controller may also control the stage and/or beam scanners to produce alternative scanning patterns. For example, the controller may scan the beam or probe across the sample in space-filling curve patterns. Space-filling curves may include, for example, a Hilbert curve, Peano curve, or another suitable type of progressively finer scanning curve. These scans can achieve progressively finer detail over time, such as by incrementally increasing the order of the curve, allowing users to decide whether to continue scan based on coarser, earlier data.

The above methods could be applied in real-time to data as it is acquired and shown to the user immediately. The user could then cancel the acquisition if needed or manually highlight areas of interest that could be acquired at higher quality.

The charged-particle-beam microscope may comprise one or more automated sample feeders to quickly and reliably feed samples into and out of the imaging area of the charged-particle-beam microscope. This may permit moving from sample to sample with low overhead and a low amount of (or no) human intervention. Typically the samples are contained on a sample storage medium. In one version, for example, the automated sample feeder comprises a magazine system for feeding a sample storage medium that comprises sample sticks into the microscope. In another version, the automated sample feeder comprises a grid tape loader (GTL) for feeding a sample storage medium that comprises flexible tape containing a plurality of samples through the imaging area of the microscope.

Furthermore, the samples may be identified and tracked. If the samples are fed into the EM by tape, for example, an identification (ID) code may be placed on the tape adjacent to, or otherwise in a predefined location relative to, the samples to uniquely identify the samples. The ID code may be, for example, a visual pattern, QR code, or barcode.

The sample storage medium may comprise a mechanical carrier (e.g., a conveyer material) and a sample substrate (e.g., a TEM support film). The mechanical carrier and sample substrate may serve two distinct and separate purposes but, when combined, can tie together elements of the sample preparation with imaging and data acquisition. For example, the carrier may interface with the mesoscale (i.e., human-scale) handling, and the substrate may interface with the data acquisition (i.e., nanoscale) handling, tying two segments of the pipelined process together through reliable and robust sample delivery.

Versions of such sample storage media include embodiments of “sample sticks.” Numerous examples of sample sticks are described in U.S. patent application Ser. No. 17/079,413 filed Oct. 23, 2020, to Christopher S. Own, which is incorporated herein by reference in its entirety. These sample sticks may be used as, for example, the “sample sticks” referenced in U.S. patent application Ser. No. 16/355,704 to Christopher S. Own. The cartridge referenced therein may support a grid stick or chip stick inside an apparatus for microscopy, inspection, or analysis.

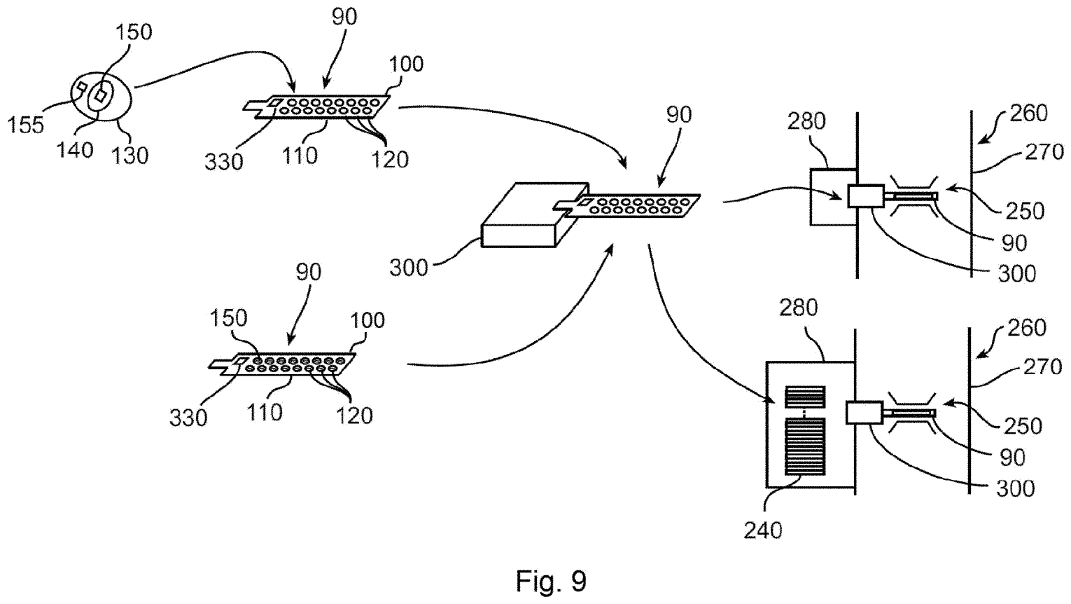

In one version, the sample stick is a “grid stick” that includes a mechanical carrier (or “stick”) that forms the main body and is adapted to permit positional precision relative to the stage motor positioning. FIG. 9 illustrates an example of an embodiment of a sample stick 90 that is a grid stick 100. Mechanical carrier 110 of grid stick 100 may comprise aluminum, beryllium, titanium, phosphor bronze, graphite, silicon, or ceramic. Further, grid stick 100 may have a conductive coating applied to surfaces exposed to the apparatus's charged-particle beam to prevent charge buildup which may affect imaging.

Mechanical carrier 110 may have an array of apertures in one or two dimensions. For example, each mechanical carrier 110 may contain from about 10 to about 100 apertures 120 suitable for use in, for example, a TEM. In one example, apertures 120 may be sized to be from about 0.5 mm to about 3 mm in diameter (or length and width dimensions).

Apertures 120 within mechanical carrier 110 may each have a sample support 130 therein to support a sample in the aperture. Sample supports 130 may be, for example, conventional TEM support grids such as mesh grids, bar grids, hex grids, or open/aperture grids. Sample supports 130 may have dimensions that are manipulable using handheld tweezers, such as an in-plane dimension of from about 0.5 mm to about 20 mm, such as an in-plane dimension of about 3 mm. Sample supports may have a thickness of from about 10 μm to about 1 mm. Sample supports 130 may comprise one or more of the materials described for mechanical carrier 110, or semiconductor or ceramic materials.

Mechanical carrier 110 or sample supports 130 may also comprise a membrane 140 over each of sample supports 130. Membrane 140 should be sufficiently mechanically stable to hold a sample 150. The combination of sample support 130, membrane 140, and sample 150 may be referred to as a “TEM sample” in a traditional sense. For example, the combination of sample support 130, membrane 140, and sample 150 can be used as “sample carrier 650” in U.S. Patent Appl. Pub. No. 2019/0287759 to Christopher S. Own et al. Membrane 140 may have a thickness of from about 10 nm to about 800 nm. Membrane 140 may comprise, for example, carbon, Formvar, silicon nitride, aluminum nitride, polyimide, or a thin deposited metal.

Mechanical carrier 110 or sample supports 130 or may have patterned structural features 145 to strengthen the capability of grid stick 100 or contained sample support 130 to hold a relatively large sample in a relatively large aperture. Such structural features 145 may include, for example, joists and ribs.

Sample identifiers 155 may be created near samples 150 such that each identifier 155 uniquely identifies an individual samples 150. Sample identifiers 155 may include, for example, a barcode, a QR code, human-readable digits, or an RFID tag. For example, sample identifiers 155 may be provided on sample supports 130, as shown in the example of FIG. 1. Sample identifiers 155 can permit efficient and accurate tracking of individual samples 150 when handling large numbers of samples 150. For example, sample identifiers 155 may permit an ordered set of samples 150 to be imaged nonsequentially and then the images to be automatically reordered as intended.

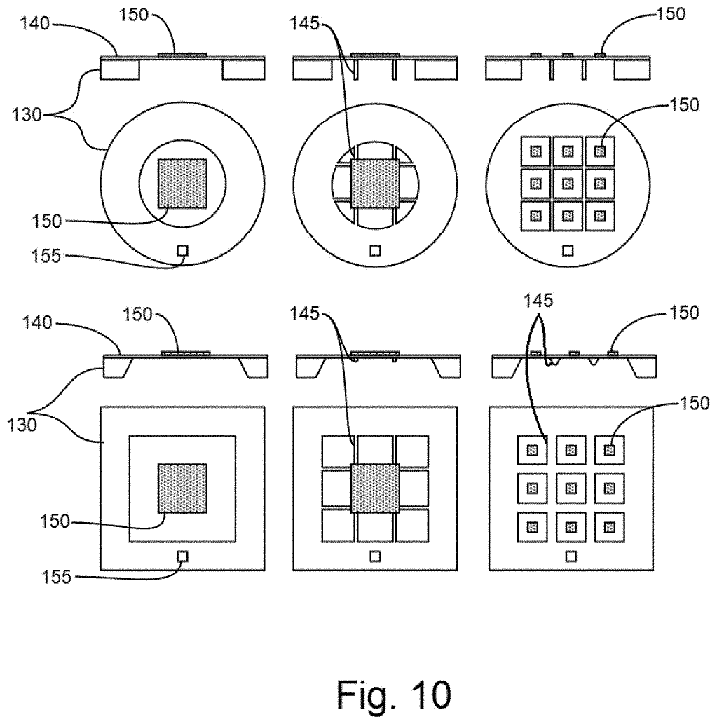

FIG. 10 illustrates cross-sectional and top perspective views, respectively, of six examples of different embodiments of sample support 130, membrane 140, structural features 145, sample 150, and sample identifier 155 implemented in grid stick 100.

Alternatively, sample stick 90 may comprise a “chip stick.” FIG. 1 also illustrates an example of an embodiment of a chip stick 160. Chip stick 160 may also comprise a mechanical carrier 110 that is monolithically fabricated to have an array pattern of multiple support membranes 140 at apertures 120, on which samples 150 are held. In chip stick 160, a specially patterned version of mechanical carrier 110 can take the place of sample supports 130. The carrier material may be, for example, semiconductor or copper. Support membranes 140 may have an in-plane dimension of from about 0.5 mm to about 1 cm while still maintaining transparency to the probing radiation, for example fast electrons. Support membranes 140 may have a thickness of from about 1 nm to about 500 nm. The support material may be, for example, silicon nitride or organic-based membranes.

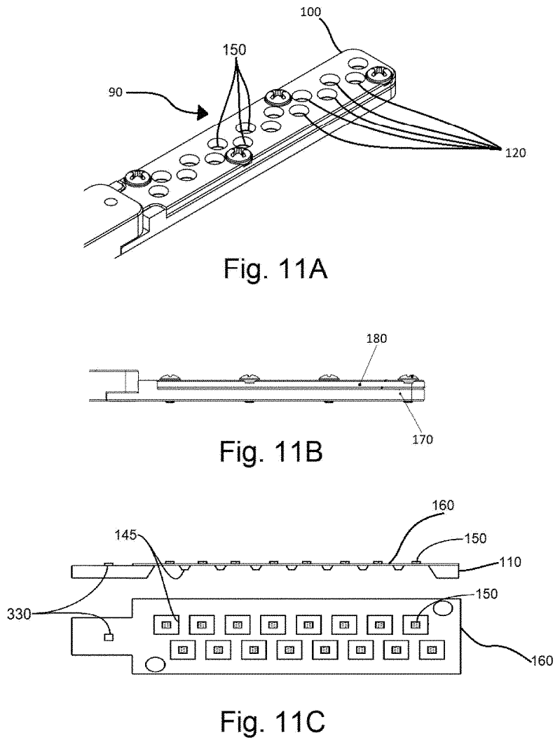

FIGS. 11A and 11B illustrate a perspective view and a side view, respectively, of another example of an embodiment of grid stick 100. Grid stick 100 has a two-dimensional array of apertures 120. In this embodiment, grid stick 100 comprises a sample tray 170 and a sample clamp 180 that clamps a plurality of support membranes (e.g., “grids”) 140 between them at the site of each aperture 120. Support membranes 140 thereby support samples 150 in apertures 120. In other embodiments, glue is used instead of clamp 180 or instead of clamp 180 there may be a partial clamp.

In the case of chip stick 160, chip stick 160 can take the place of sample clamp 180 and possibly even sample tray 170 (for example, chip stick 160 may be positioned upside down to protect delicate membranes 140) while a specially patterned mechanical carrier 110 of chip stick 160 also acts as sample supports 130. FIG. 11C illustrates cross-sectional and top perspective views, respectively, of such chip stick 160.

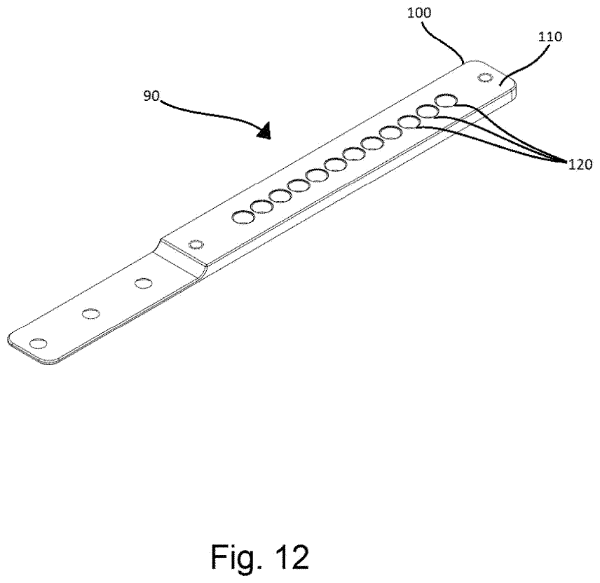

FIG. 12 illustrates a perspective view of sample tray 170 of yet another example of an embodiment of grid stick 100. In this embodiment, grid stick 100 has a one-dimensional array of apertures 120. This version of grid stick 100 may be used for cut sections of tape where each tape section contains multiple samples, taken from a larger continuous reel of tape that may have had a large plurality of samples sequentially deposited in a continuous process.

In one version, preparation of each of grid sticks 100 or chip sticks 160 comprises picking up samples 150 and placing them in the sample supports or support membranes of sticks 100, 160. In one embodiment, samples 150 are picked up from a water boat using a loop. Samples 150 may have been prepared, for example, by serial sectioning by a diamond knife or microtome. The loop is a tool with a wire loop at its end and a handle for manipulation that can be used to transport thin sections by taking advantage of meniscus forces of water. The wire loop may be treated with, for example, a coating to enhance its properties of interacting more reliably with the fluid and sample being picked up. The loop may be manipulated by one or more motors in one or more degrees of freedom, including translation and tilt. After being picked up, sample 150 is held in the loop by surface-tension forces of a droplet or other quantity of liquid that has been transferred from the water boat. The loop is used to deposit sample 150 on one of the sticks. During deposition, some of the liquid may also transfer to sample stick 100, 160, and that liquid may be evaporated, such as by application of suitable heat to sample stick 100, 160. The picking up and/or deposition of samples 150 may be performed either by a human operator or robotically, and may be assisted by machine vision to ensure reliability and robustness of the pickup and deposition process.

Semiconductor processes allow efficient patterning of circuits, magnetic structures, and/or optical features (e.g., fiducials) into supports 130 or mechanical carriers 110 that may be adapted to manipulate and/or sense samples either during the deposition of samples 150 or after the deposition of the samples. For example, application of electrostatic and/or magnetic fields may be used to manipulate the samples which are typically delicate and cannot be easily manipulated using macroscopic mechanical tools such as tweezers. Thus, such features patterned into supports 130 or mechanical carriers 110 can be used to orient the samples in a desired direction or apply a desired amount of tension to samples 150 to straighten samples 150.

In various examples, one or more of an electromagnetic coil, heater, and electrostatic guide wire may be patterned in membrane 140. Samples 150 may also have features that are complementary to patterns in membrane 140 to enhance the ability to manipulate and/or sense the presence of samples 150. These features may be patterned using standard semiconductor lithographic physical vapor deposition and etch processes, or more sophisticated methods such as chemical vapor deposition or atomic layer deposition, which allows complex heterogeneous structures to be patterned with varying efficiencies.

Grid sticks 100 or chip sticks 160 may be heterogeneous. For example, chip sticks 160 may have a metal substrate under mechanical carrier 110 to enhance their toughness. Grid sticks 100 or chip sticks 160 may also have one or more manipulation features (e.g., at the mesoscale, the scale of a human or robot operator) to allow a human or machine operator to handle grid sticks 100 or chip sticks 160.

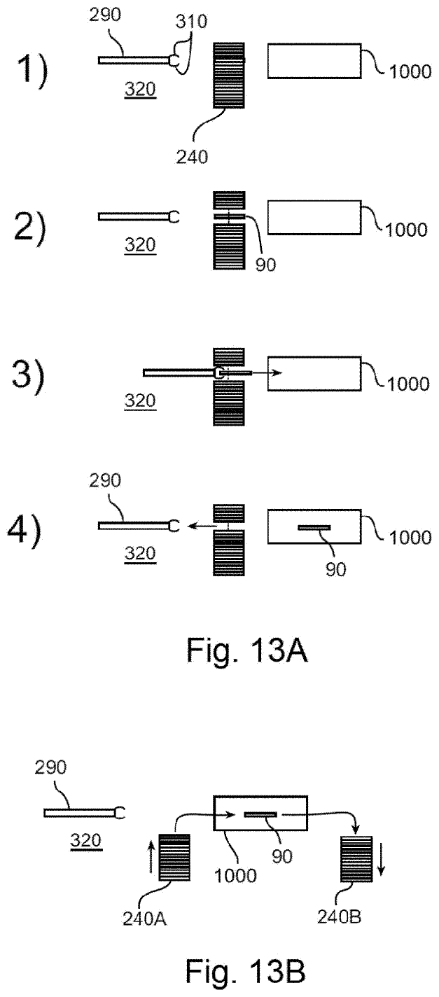

Returning to FIG. 13A, multiple grid sticks 100 and/or chip sticks 160 may be stored in a magazine 240 and accessed from magazine 240 as needed. Magazine 240 may store sticks in an array configuration, such as a one-dimensional (e.g., “stack”), two-dimensional, or three-dimensional array. Magazine 240 may be adapted to store and permit access to from tens to hundreds of grid sticks 100 or chip sticks 160. Magazine 240 may allow efficient, reliable, and robust transfer of grid sticks 100 or chip sticks 160 into a vacuum chamber, whether that vacuum chamber is for microscopy, inspection, or analysis either serially or by random access. Magazine 240 may also be adapted to prevent scraping or impingement damage of grid sticks 100 or chip sticks 160 and samples 150 carried therein. Grid sticks 100 and/or chip sticks 160 may have features, such as wells or channels, to protect samples 150 from damage when stacked in magazine form.

Magazine 240 may allow random or sequential access to grid sticks 100 or chip sticks 160. FIG. 13A is a schematic illustration of an example of an embodiment of such a scheme. Magazine 240 may split at the location of a randomly-accessed sample stick 90 (e.g., grid stick 100 or chip stick 160) and a mechanism (e.g., friction mechanism, such as a transfer arm with an effector, such as gripping fingers) may access the addressed stick 90. The addressed stick 90 may be gripped and withdrawn by the mechanism.

An automated sample-feeder may be provided to deliver samples 150 to, and/or remove samples 150 from an imaging area 250 of microscope 1000. For example, the automated sample-feeder may transfer samples 150 between the interior of the apparatus's vacuum chamber 270 and an external storage unit, such as one or more magazines 240 of grid sticks 100 or chip sticks 160.

In one embodiment, magazine 240 may serve grid sticks 100 or chip sticks 160 sequentially. FIG. 13B is a schematic illustration of an example of an embodiment of a sequential automated sample-feeding scheme. Sticks 100, 160 may be drawn sequentially from the top or bottom of a source magazine 240A that is being shifted by an elevator. After processing, sticks 100, 160 may be stored sequentially at the top or bottom of a destination magazine 240B that is also being shifted by an elevator.

Magazine 240 may be held at atmosphere while grid sticks 100 or chip sticks 160 are accessed for microscopy, inspection, or analysis. Alternatively, magazine 240 may be held at vacuum. In another embodiment, magazine 240 is held in an isolated, clean airlock 280 at atmospheric pressure. In yet another embodiment, the microscope controller changes the pressure in airlock 280 while imaging is occurring; in this embodiment, the magazine can be reconfigured after airlock 280 is brought back to atmospheric pressure.

Magazine 240 may further be adapted to heat, chill, or provide a gaseous treatment to grid sticks 100 or chip sticks 160 For example, magazine 240 may heat all sticks contained therein simultaneously to drive off impurities from samples to enhance imaging quality.

Further, grid sticks 100 and chip sticks 160 may simplify indexing of samples 150, and entire volumes of samples 150 may thereby be tracked simply and efficiently. Each aperture 120 (i.e., sample) on one of sticks 100, 160 may be addressed separately. Alternatively, all of apertures 120 on one of sticks 100, 160 may be addressed together, or all of apertures 120 in a single one of magazines 240 of sticks 100, 160 may be addressed together.

One or more identification patterns 330 may be created on sample stick 100, 160 temporarily or permanently to uniquely identify individual sample sticks 100, 160. For example, identification pattern 330 may be a removable sample label that is placed on sample stick 100, 160 or patterned onto sample stick 100, 160 using an electron beam of an electron microscope adjusted with elevated current in the example where the apparatus is an electron microscope. The patterning could be carried out on a beam-sensitive label area of sample stick 100, 160, comprising, for example, a beam-sensitive sacrificial polymer, or an etchable substrate catalyzed by exposure to a charged-particle or light beam. Alternatively, identification pattern 330 may be etched onto sample stick 100, 160. In one example, identification pattern 330 is etched onto chip stick 160 by a lithographic step in the process of manufacturing chip stick 160. Identification pattern 330 may contain a unique identification code that can be determined when the pattern is read by one or more means. For example, identification pattern 330 may comprise a miniature bar code, QR code, or another type of code based on a geometric pattern. The pattern may be visible to photons and/or charged particles. In another example, identification pattern 330 may be registered in an RFID chip. The identification code may be inserted into the metadata of the patterned images for the samples on that sample stick, providing convenient tracking of samples 150.

A reference pattern may also be placed on grid stick 100 or chip stick 160 to enable quick calibration of a charged-particle-beam microscope, such as focusing, rotation calibrations, and magnification calibrations, by imaging of the reference pattern. For example, the microscope may perform this calibration substantially automatically. The reference pattern may be placed at a predetermined location of stick 100, 160. The same reference pattern may be used on different sticks to enable microscope 1000 to be calibrated by imaging the reference pattern.

Furthermore, a combination identification/reference pattern may be provided in which the pattern provides an identification code and the same pattern is also used for calibration of the apparatus (such as an electron microscope). In this version, the apparatus may, on insertion of sample stick 100, 160, read the identification code from the pattern and simultaneously calibrate microscope 1000 based on the pattern, readying microscope 1000 for imaging of samples 150.

The microscope may have a cartridge to support and precisely move one or more samples 150 in the imaging area. The cartridge may contain one or more actuators, such as motors, that are disposed inside or nearer the imaging area (e.g., within the vacuum chamber) than with conventional sample stages. In one version, the cartridge is adapted to hold a sample stick 90 that supports one or more samples 150.

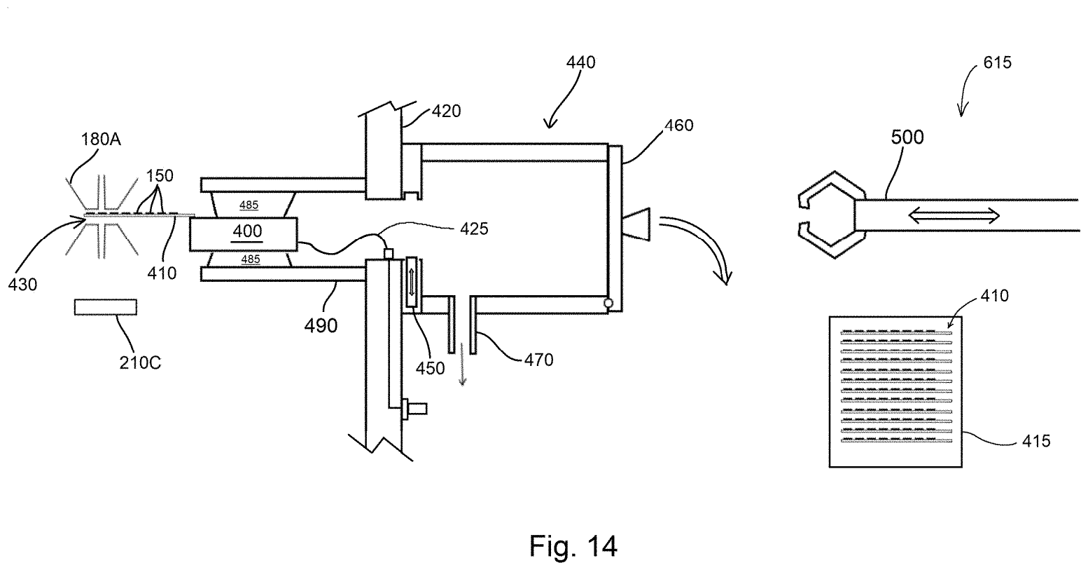

FIG. 14 illustrates a schematic side view of an example of an embodiment of a charged-particle beam microscope and a cartridge 400 that is inserted into vacuum chamber 420 and to move samples 150 in the imaging area 430. Cartridge 400 may implement aforementioned stage 1185, such as on cartridge 400 itself or on a sample stick held by cartridge 400.

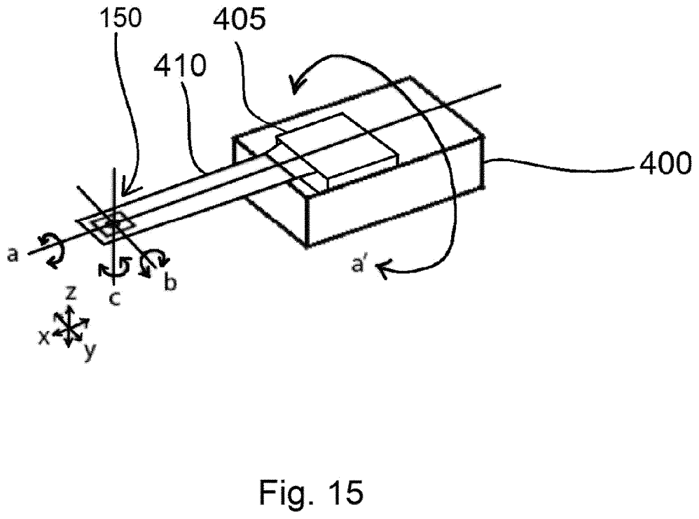

Cartridge 400 may impart motion to sample 150 in multiple directions, which may include linear and rotational directions. For example, in one embodiment, illustrated in FIG. 15, cartridge 400 provides motion in ‘x’ and ‘y’ directions. Additionally, however, cartridge 400 may provide motion of sample 150 in one or more of the ‘z’ direction and one, two, or three rotational directions, as shown in FIG. 15.

The localization of the actuators inside or near imaging area 430 (e.g., within vacuum chamber 420) may reduce lossy or unstable linkages and/or interferences. Losses in mechanical linkages can include, for example, hysteresis in a linkage, an imprecision from necessary clearances in a rotary shaft linkage, or an inelastic deformation of a lever. Instabilities can include, for example, sensitivity to a vibration that is amplified through a lever of a linkage or resonances in a complex linkage.

The actuators of cartridge 400 may be configured to impart motions to sample 150 by movements in the actuators that are on the same or a substantially similar order of magnitude as the sample movements. Similar orders of magnitude in this context may be, for example, less than or equal to two or three orders of magnitude. In contrast, a conventional stage may attempt a reduction in the order of magnitude of motions of about four or seven.

The actuators may include stick-slip, piezo walker, or vibratory motors based on piezos or micro-actuators. For example, the motors may include one or more piezoelectric motors that are capable of moving the stage very quickly and smoothly so that short exposures on the order of milliseconds or microseconds can be practically achieved. The piezoelectric motors may also be adapted to move sample 150 with very high positional precision. The actuators may alternatively include, for example, voice coils.

It may also be advantageous to mechanically decouple cartridge 400 from the environment outside vacuum chamber 420 of microscope 1000 to improve mechanical isolation of sample 150 from instabilities originating outside vacuum chamber 420. In conventional apparatuses, it may be inefficient and imprecise to produce small motions of the sample inside or near the imaging area by originating motions substantially distant from the imaging area. Such small motions may be on the order of nanometers or smaller. In the case of a TEM or STEM, “distant” may refer to, for example, a distance of at least about 20 cm.

Cartridge 400 may additionally improve thermal isolation of the sample motions from outside imaging area 430. Thermal modulations can cause, for example, expansions and/or contractions of materials that unpredictably affect sample positioning and therefore imaging quality.

Further, cartridge 400 may improve electromagnetic isolation of the sample motions. For example, stepper motors for a sample stage may generate electromagnetic interference that could adversely affect charged-particle beam 1050. The improved electromagnetic isolation may therefore advantageously improve the tolerance of the imaging system to a stepper motor drive circuit that may be operating with an electromagnetically noisy type of signal such as pulse-width modulation (PWM).

Cartridge 400 may be shaped and sized to be inserted into vacuum chamber 420 through an opening of limited size. For example, although cartridge 400 may contain multiple actuators to provide motion in a plurality of dimensions, cartridge 400 may be adapted to be substantially compact in form factor. In one embodiment, cartridge 400 is smaller than 10 cm×10 cm×10 cm.

Returning to FIG. 14, an airlock 440 may be provided to allow venting to air without requiring venting of vacuum chamber 420. Airlock 440 may therefore permit the removal and insertion of cartridges 400 in relation to vacuum chamber 420 without necessitating venting of vacuum chamber 420. Airlock 440 may include one or more valves 450 to selectively isolate the atmosphere inside airlock 440 from the atmosphere inside vacuum chamber 420. Airlock 440 may also have a door 460 that can be opened to allow access to the interior of airlock 440 and can be closed before vacuum pumping the interior of airlock 440. Airlock 440 may further have a pumping outlet 470, and may have a dedicated vacuum pump, to allow evacuation of the atmosphere inside airlock 440. For example, in one embodiment airlock 440 can have a speed of vacuum cycling of less than about 10 minutes. Cartridge 400, or even just sample stick 410, can be inserted or removed while maintaining the vacuum in vacuum chamber 420.

The combination of insertable cartridge 400 and airlock 440 may significantly reduce or eliminate overhead associated with sample exchange and/or transfer, sample positioning, and related user interventions.

An anchor 485 may be provided to support cartridge 400 inside vacuum chamber 420. Anchor 485 may be configured to be substantially stable in relation to the observation area 430, such as objective lens polepiece 180A. Mechanical stability of anchor 485 may include, for example, positional and thermal stability. In one embodiment, anchor 485 is rigidly attached to the frame of the apparatus, such as attached to a wall of vacuum chamber 420 directly or by a support structure 490. In another embodiment, such as in a TEM or STEM, anchor 485 may be rigidly coupled to a polepiece of an objective lens. Meanwhile, anchor 485 may be decoupled from the environment external to vacuum chamber 420. Anchor 485 may hold cartridge 400 by, for example, complementary frictional elements on the anchor and cartridge.

A transfer arm 500 may be provided to transfer cartridge 400, or even just sample stick 90, between airlock 440 and the vacuum chamber 420, and/or between the external environment and airlock 440. Transfer arm 500 may be operated manually or robotically, such as automatically. Transfer arm 500 may use, for example, a screw retention mechanism, a clamping or gripping mechanism, or a magnetic or electromagnetic grabber to attach itself to cartridge 400 for movement of cartridge 400, or to sample stick 410 for movement of sample stick 410. Transfer arm 500 may also have gripping fingers, which may be actuated by gears, pulleys, or any other suitable mechanism. Cartridge 400 may have an attachment region that is substantially robust to contact with transfer arm 500 for secure attachment of transfer arm 500 during movement.

Cartridge 400 may be communicatively coupled to the environment outside of vacuum chamber 420 for signal transmission and/or reception across the vacuum-retaining wall. The signals may be transmitted electrically or optically. For example, the signals may be transmitted from outside of vacuum chamber 420, such as from the controller, to the actuators of cartridge 400. Additionally, signals may be transmitted from cartridge 400 to outside of vacuum chamber 420, such as to provide feedback about cartridge 400. In one example, a microencoder provides feedback to the controller about the actuated position of cartridge 400.

In one version, cartridge 400 may be communicatively coupled to outside of vacuum chamber 420 by fine, highly flexible electrical wires 425. These may include, for example, one or more stranded multi-filar conductors of a gauge thinner than, e.g., 28 AWG. Electrical wires 425 may be bundled and/or shielded.

In another version, cartridge 400 may be communicatively coupled to outside of vacuum chamber 420 by electromagnetic transmission, such as radio or optical transmission. For example, the transmission may be implemented using Wi-Fi or Bluetooth protocols.

Sample sticks 100, 160 may be swapped into and out of the imaging area automatically, such as from a magazine 415 of sample sticks 100, 160. For example, an airlock 280 may be provided to allow venting to air without requiring venting of the vacuum chamber 270 of the microscopy, inspection, or analysis microscope 1000. A transfer arm 290 may be provided to transfer cartridge 300, or to directly transfer sample stick 100, 160, between airlock 280 and vacuum chamber 270, and/or between the external environment 320 and airlock 280. Transfer arm 290 may be operated manually or robotically, such as automatically. Transfer arm 290 may use, for example, a screw retention mechanism, a clamping or gripping mechanism, or a magnetic or electromagnetic grabber to attach itself to cartridge 300 for movement of cartridge 300, or to sample stick 100, 160 for movement of stick 100, 160. Transfer arm 290 may also have gripping fingers 310, which may be actuated by gears, pulleys, or any other suitable mechanism. Cartridge 300 or stick 100, 160 may have an attachment region that is substantially robust to contact with transfer arm 290 for secure attachment of transfer arm 290 during movement.

In another version, the automated sample-feeder may additionally or alternatively include a track or belt conveyer for moving cartridge 300 from an interior of airlock 280 to an anchor inside the observation area in vacuum chamber 270. Samples 150 may be sequentially loaded and independently indexed using cartridge 300 and airlock 280 and/or sample sticks 100, 160 containing multiple samples 150.

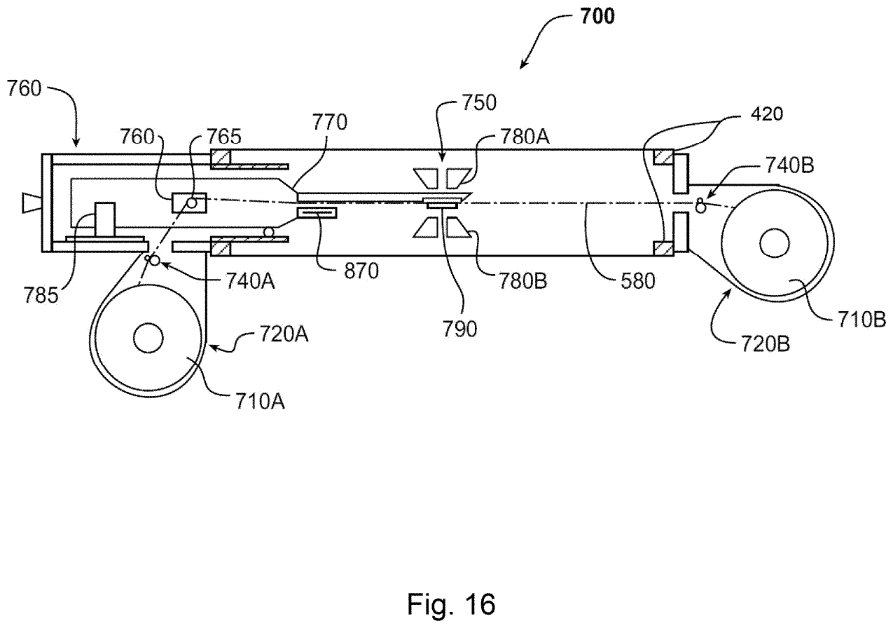

Another version of the automated sample feeder may comprise a grid tape loader (GTL) for feeding a sample storage medium that comprises flexible tape containing a plurality of samples. FIG. 16 is a schematic diagram of an example of an embodiment of grid tape loader 700. One or more reels 710A, B may be used to store tape 580. Tape 580 is rolled onto a feed reel 710A in feed housing 720A. A takeup (i.e., collection) reel 710B may be provided in a takeup housing 720B. During operation, tape 580 with samples is provided by feed reel 710A, advances through the system, and is taken up and stored in takeup reel 710B.

Feed reel 710A and/or takeup reel 710B may be stored at vacuum. In one embodiment, both reels 710A, B may be stored outside the charged-particle-beam column. Automated sample-feeder 700 may have a load lock housing 730 to allow easy tape loading. In an alternative embodiment (not shown), one or both of reels 710A, B may be stored within the body of the charged-particle-beam column rather than outside of it.

In another version, the reels are stored at air pressure. A feedthrough connecting air and vacuum volumes is provided to enable transfer between differing volumes without damage to the samples on the carrier. This may take the form of a “whistler” interface which may comprise a slit or series of slits that provide for transitions between air and vacuum. Another embodiment of a slit-based interface might provide for a separator comprising a suspension of viscous yet inert fluid, for example ferrofluid, which is retained at each slit position but enables free progression of the tape and sample without damaging the samples or leaving fluid residue.

In one version, the automated sample-feeder uses two drives to progress the tape, such as shown in FIG. 16. For example, two drives 740A, B may be positioned symmetrically about an analysis section 750 of automated sample-feeder 700 that is inside the microscope, comprising one drive on each side of analysis section 750. Tape 580 can be progressed in either one or both directions (the two directions being backwards and forwards). Each of drives 740A, B may be a friction (i.e., pinch) drive comprising two wheels that sandwich tape 580, at least one of these being wheels driven by a motor. At least one wheel surface grips tape 580 so that tape 580 advances while the wheel is being driven. An alternative method of driving tape 580 is to use a sprocket drive. A clutch may be provided in the drive system to limit the torque on drives 740A, B so as to prevent overtensioning tape 580.

In another version (not shown), the system may alternatively use only a single active drive in combination with a controllable clamp. This drive system may be asymmetric, comprising a drive and a clamp on either side of the analysis section. In this case, the automated sample-feeder can operate using a single on-off control for the clamp combined with full control of the single drive. This is in contrast to the two-drive system, in which two fully controllable active drives are used. A clamping force limiter may be provided in the case of an asymmetric drive/clamp system so as to prevent overtensioning the tape.

The one or two drives may apply a small (nondestructive) torque to one or both of feed and takeup reels 710A, B to ensure that tape 580 is compactly packed onto reels 710A, B during release and takeup. Automated sample-feeder 700 may also have a specialized tension meter 760 to measure the tension of flexible tape 580. The measured tension in tape 580 may be used, such as by the controller, to control the relative speed of the two drives so as to keep the tape tension constant, or prevent damage to delicate films or samples carried on tape 580 by keeping the tension under a critical value. Tension meter 760 can also detect any slippages, breaks of the tape, or motor malfunction of the tape drives.

In one embodiment, tension meter 760 includes a strain gauge that is attached to a roller 770 that is used to guide tape 580. Roller 770 may have the shape of a wheel, and tape 580 may glide over roller 770. Roller 770 may have an inverted top hat profile at its surface to enable contact of roller 770 with tape 580 to both sides of the samples, such that the samples can pass freely over roller 770 without coming into direct contact with the roller surface. Tape 580 may trace the radius of roller 770, resulting in the concave side of tape 580 exerting a force on roller 770. An axle on which roller 770 spins may transfer this force via a frame to an elastic bending element, which may be fastened to the body of the cartridge. This elastic bending element may comprise a thin metal sheet with a strain gauge cemented onto its surface. When the metal sheet bends in response to the force, the strain gauge reports a change in the measured strain, corresponding to a change in tension of tape 580. Thus, tension meter 760 can report the current tension of tape 580.

Grid tape loader 700 may have a cartridge 770 that traverses into analysis section 750 of microscope 10 and that is adapted to guide tape into, and support samples within, analysis section 750. Analysis section 750 may be inside the objective lens of microscope 10, such as between upper and lower pole pieces 780A, B of the objective lens. Cartridge 770 may be configured to guide the tape through (or around) its body so as to transfer the samples into analysis section 750. Furthermore, cartridge 770 may be sized and shaped to fit within analysis section 750 without significantly disrupting the normal operation of the objective lens.

Cartridge 770 may be further configured to translate and/or tilt each sample within analysis section 750. In one embodiment, cartridge 770 may provide axial (i.e., “x-axis” along the tape feed direction) motion by moving its own body relative to a reference plane (e.g., the column load lock interface). In this embodiment, cartridge 770 may provide height (i.e., “z-axis”) and tilt (α and/or β) motion by moving a carriage 790, which holds the portion of tape 580 that is in analysis section 750, relative to the rest of cartridge 770. A micromotor assembly 785 may drive the movement of cartridge 770.

Finally, in this embodiment, carriage 790 may provide motion of the sample in the axis (i.e., “y-axis”) transverse to the tape feed direction and parallel to tape 580 by moving the sample relative to carriage 790. The y-axis may be used as the “fast” axis and the most responsive axis, such as due to the small moving mass of the portion of carriage 790 that moves in the y-axis. For example, carriage 790 may translate samples as fast as or faster than 1 μm/ms, and settle faster than about 500 ms.

Carriage 790 may use a miniature motor assembly to move the sample. Furthermore, the miniature motor assembly may contain primarily or exclusively nonmagnetic and vacuum-stable materials. Some examples of such a miniature motor assembly include a piezomotor assembly, voice coil drive, coil drive that acts against the magnetic field of the EM lens field, or even mechanical linkages (e.g., levers, pistons, pulleys) connecting outside forces to the analysis section.

Carriage 790 may have a clamping mechanism to keep tape 580 substantially flat, uniform, and stable within the analysis section during imaging. This clamping system may also serve to provide positive electrical contact between the tape and carriage body. This clamping mechanism may include a spring-loaded frame or frame elements whose applied tension on the sample is easily overcome in the axial direction of the tape by the tape drives.

Furthermore, a spring-loaded clamp may have an active release system to temporarily decrease or release its tension entirely, for example using a piezo actuator, enabling the tape to advance freely. Alternatively, the clamp may be an active clamp that is turned on by activating a piezo actuator, such that the tape advances freely except when the clamp is actuated.

Cartridge 770 may incorporate an ID reader 870 along the tape path, to read the ID codes described above. For example, the ID reader may have an optical sensor located near the analysis section. The ID reader may optionally be placed anywhere in the system where it is convenient to read ID codes from the tape.

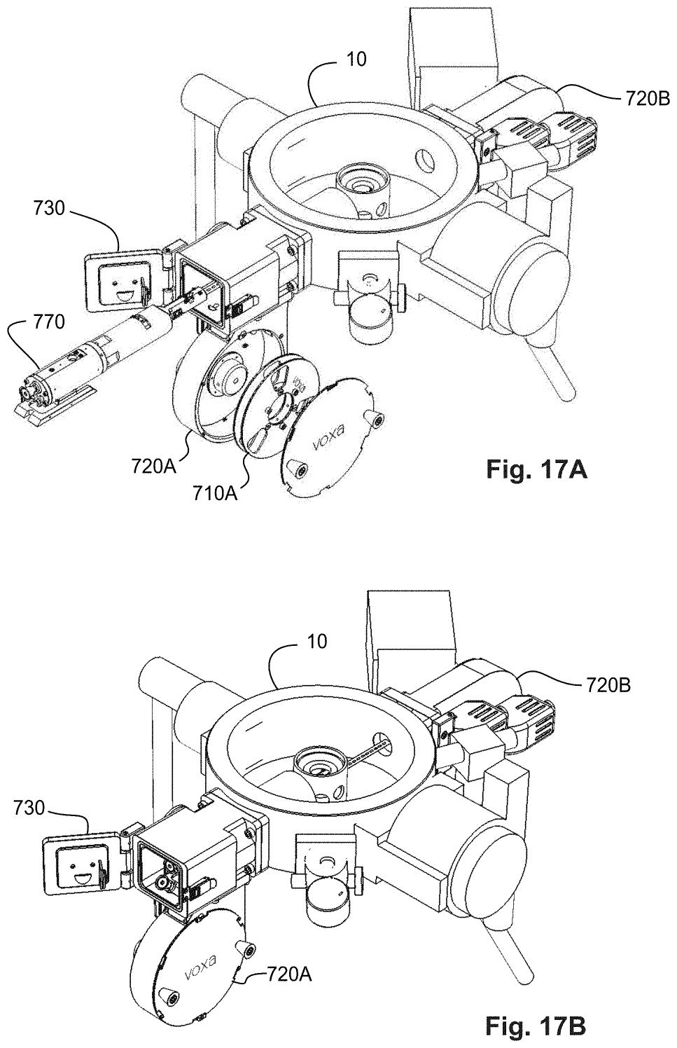

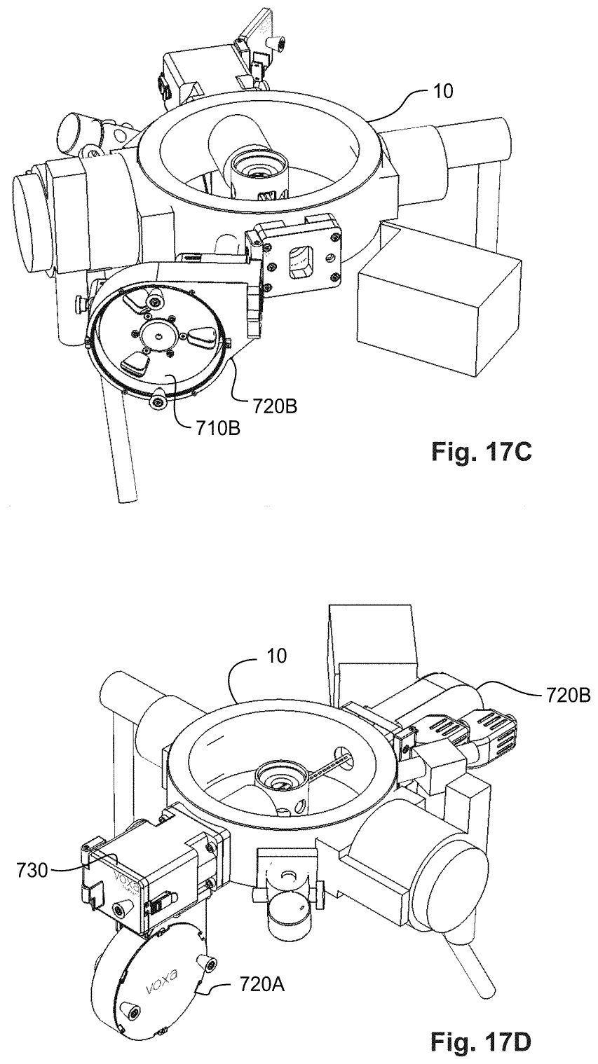

To prepare the automated sample-feeder for operation, a tape containing samples may be loaded into the feed reel. An example is shown in FIG. 17A. A leader (i.e., initial) section of the tape may be threaded from the feed section through the analysis section and into the takeup section. The leader tape may be advanced from the feed reel section into the load lock. Then, the leader tape may be threaded through the cartridge outside the load lock. The cartridge may be inserted into the load lock. (The cartridge in this particular aspect may act as an arm that transfers tape into the microscope system during loading.) The tip of the cartridge, which contains the carriage (with the “y-axis” drive) holds a short section of the leader tape and transfers it through the analysis section (e.g., between the objective lens pole pieces) and through to the takeup side. An example is shown in FIG. 17B. The leader tape may be captured and advanced through a takeup load lock into the takeup section, and finally threaded onto a takeup reel. An example is shown in FIG. 17C.

In one embodiment, the entire column and reel housings may be brought up to air during load or unload of a tape. When the system is at air pressure, tape can be loaded into the cartridge, and the cartridge can be inserted and affixed within the column and load lock assembly. The reels can then be loaded and closed off, and the column may be pumped down to operating vacuum. An example is shown in FIG. 17D.

There are a number of different methods for preparing samples and sample media. These methods can have varying difficulty, cost, and efficiency. The sample preparation method can be selected or adapted to the information about the samples that is desired.

In one example of sample preparation, tissue can be stained and fixed (e.g., fixing the proteins in place and hardening the tissue for accurate structural metrology and increasing handling robustness of the sample). The fixed tissue can then be serial-sectioned placed onto serial sample supports. In this case, the samples are serially related to each other. Gaps in the samples (such as due to damage or miscuts) can be deleterious to the integrity of the acquired data set.

However, an automated microscope system can prevent such gaps in the samples from being extremely harmful or fatal to the integrity of the data set. For example, the controller may execute an imaging algorithm containing one or more pattern recognition algorithms to automatically detect missing or damaged sections.

An automated microscope system may also include mechanisms to keep the tension of a conveyor belt or grid tape in an automated sample feeder under certain limits and/or detect a misfeed. If the controller detects a misfeed, it may, for example, either pause image data acquisition and ask for human assistance or attempt a finite number of retries to attempt to rectify the situation or learn more information about the problem.

Testing protocols also allow identification of failure modes leading to classification of failure modes that can be minimized through adjustment of specific mechanical adjustments. Examples of mechanical adjustments are traction, slip threshold clutches, overdriving to account for momentary slippage, and suspension tuning. Voxa™ does a combination of accelerated testing and simulated sample exchange movements using substrates that have less value than those containing real samples. We have a cloud-based “fleet manager” that allows predictive control and identification of failure modes that have the necessary statistics to predict the reliability of the system as a whole at scale. The “fleet manager” can also recommend tests to be performed on respective microscopes.

In another example of sample preparation, construction or demolition waste material is diluted and evaporated onto a sample support. Advantages of such a method may include being extremely simple, highly automatable, and parallelizable using parallel fluid handling systems.

In yet another example, hazardous nanoparticles or biological agents or industrial agents in the air may be detected by transferring catchment membranes by way of dissolution, concentration, and then fluid transfer and evaporation onto substrates.

Another example of sample preparation comprises micromechanical deposition, such as molecular threading. See, e.g., Payne AC, Andregg M, Kemmish K, Hamalainen M, Bowell C, et al. (2013) Molecular Threading: Mechanical Extraction, Stretching and Placement of DNA Molecules from a Liquid-Air Interface. PLoS ONE 8(7): e69058. doi:10.1371/journal.pone.0069058, which is incorporated herein by reference in its entirety.

In still another example of sample preparation, a method of directed positioning is used to locate the sample on a sample stick in a desired location and orientation. This may include, for example, embedding magnetic particles in a portion of the sample stick and using an applied magnetic field to apply one or more forces to those embedded magnetic particles to precisely manipulate the position of the sample stick when the sample is placed on the sample stick.

The controller (e.g., controller 600) of the charged-particle-beam microscope (e.g., microscope 1000) may, for example, receive inputs from a human user, provide instructions or other signals to components of the microscope, and/or perform data processing of signals detected by the microscope to generate and process images. For example, the controller may control the components of the optical column of microscope, such as, for example, the charged-particle beam source (e.g., source 1120), beam scanners (e.g., beam scanner 1115 and beam descanner 1190), and the detectors (e.g., detector 1180), as well as the stage (e.g., stage 1185). As another example, the controller may control and/or read back data from the power supply for the charged-particle beam source filament by transmitting and receiving control commands and data. The controller may also receive signals from the detectors to be processed computationally to generate images.

The controller may include an image formation unit for this purpose. The image formation unit may be disposed within or external to the microscope column and communicate with the optical system and the stage in any fashion, such as by a direct or indirect electronic coupling, or via a network.

The controller may automatically handle one or more aspects of operation of the microscope, and may be adapted to substantially automate the operation of microscope with minimal input required from a human user. The controller can be adapted to perform multiple operations automatically. For example, sequential insertion, imaging, and removal of samples 150 into and out of an imaging area may be substantially or completely automated. For example, the controller may control transfer arm 290 as well as components of microscope 1000.

The controller may include one or more microprocessors, controllers, processing systems, and/or circuitry, or any suitable combination of hardware and/or software modules. For example, the controller may be implemented in any quantity of personal computers, such as IBM-compatible, Apple, Macintosh, Android, or other computer platforms. The controller may also include any commercially available operating system software, such as Windows, OS/2, Unix, or Linux, and any commercially available and/or custom software such as communications software or microscope monitoring software. Furthermore, the controller may include one or more types of input devices, such as for example a touchpad, keyboard, mouse, microphone, or voice recognition.

The controller software may be stored on a computer-readable medium, such as a magnetic, optical, magneto-optic, or flash medium, floppy diskettes, CD-ROM, DVD, or other memory devices, for use on stand-alone systems or systems connected by a network or other communications medium, and/or may be downloaded, such as in the form of carrier waves, or packets, to systems via a network or other communications medium.

The charged-particle beam microscope can be controlled using at least one terminal having a user interface (UI) that communicates with the microscope, such as via the controller. Either all or a subset of the functionality of each component may be exposed to the UI, such as via an application programming interface (API). The UI may automatically make changes to the components based on information it receives from the user, from other components, and/or at certain times or locations. The UI may thereby offer a simplified way to control various components of microscope.

The microscope may be operated by a portable device providing that UI in the form of hardware and/or software. The portable device may be, for example, a tablet computer, smartphone, or other consumer device. For example, this UI may be a secondary interface, where a terminal that is local to microscope constitutes the primary interface. This secondary interface can provide some or all of the functionality of the primary user interface, such as complete operation of microscope. Any number of these secondary interfaces may be adapted to control the instrument.

The UI may include a touch-screen interface to enhance interaction of the user with the microscope. For example, a pinching movement of the fingers or hand on the touch-screen may cause the image to grow or shrink. Dragging with a finger could cause the stage to move. It may also shift the current image immediately, estimating the appearance of the next image to acquire. Other gestures could perform other operations (e.g., two-finger drag could change astigmatism, etc.) The user could use a touch screen interface to perform all necessary actions on the microscope. These could include moving the sample, changing the field of view, focusing, stigmating, or otherwise tuning the image, changing the sample dwell time, changing the resolution, changing source intensity, etc. The UI may also be configured to synchronize and mediate between multiple devices connected to the microscope.

The controller and the UI may provide two-way communication between the human user and the microscope, such as feedback-based control of the microscope by the user. For example, the user may make a gesture at the UI, such as a swipe of a finger, that causes a stage movement or beam displacement to shift imaging in proportion to the swipe. The UI may then quickly refresh the image provided to the user for the new imaging location. The user may also make a gesture at the UI to change, for example, one or more imaging perspectives, brightness, or contrast, which may control detectors of the microscope, such as by turning them on or off or by triggering actuators that change the detectors' positions. For feedback-based control of the microscope, it may be desirable to have two-way communications between UI and the microscope with suitably low latency in relation to human visual and tactile senses, and at least one-way communication from the microscope to the UI with sufficiently high throughput to provide images to the user sufficiently quickly to give the user a sense of “real time” performance. In one embodiment, lower-resolution survey images may be provided to the user in substantially real time, and at a selected imaging location the user may request a higher resolution image that is not provided in real time. In one example, microscope 10 and the UI are adapted to have the stage respond to user commands with a latency of less than about 100 ms. In another example, the microscope and the UI are adapted to respond to user commands and give feedback or send a complete image from the microscope to the UI in less than about 1,000 ms, and preferably less than 500 ms.

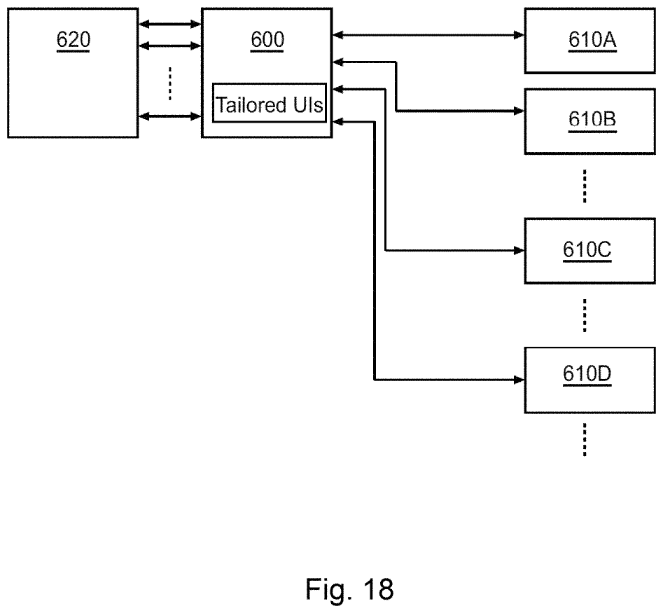

FIG. 18 is a schematic diagram of an example of an embodiment of an environment in which controller 600 serves multiple clients 610A-D. Clients 610A-D may serve as terminals having UIs. Controller 600 is connected to microscope hardware 620, which may include, for example, the optical components, detectors, stage, and power supply of the microscope. Controller 600 can thereby control the microscope and/or read back data or other signals from the microscope. Controller 600 may serve tailored UIs, which are customized for one or more of particular types of clients 610A-D.

For example, controller 600 may include a web server that provides tailored UIs to clients 610A-D as web services, which may be exposed and served based on authentication, identification, or some other request method from client. This can allow two-way communication between controller 600 and clients 610A-D. Clients 610A-D may include simple clients, such as, for example, imaging monitors, as well as complex clients, such as, for example, microscope controllers, image postprocessors, cloud storage or processing services, or microscope managers.

The controller and the UI may be adapted to attempt to perform as many operations automatically as possible. For example, starting an application, or turning the device on may be interpreted as the user wanting to operate the microscope and it can attempt to turn on the microscope automatically. This could also happen in response to actions taken on the instrument itself; e.g., closing a door could interpreted as a cue to turn on the microscope. The microscope may be kept as “on” as possible, depending on power requirements or longevity of components.

As one example, automation may be provided around the exchanging of samples in the charged-particle beam microscope (EM). Exchanging a sample may, in some embodiments, require venting to air a previously evacuated area, and may involve ramping the source voltage down to a safe level. Both steps may be performed automatically when the user starts the sample change. Once the change is complete the area is automatically evacuated and the high voltage automatically turns on. (If the instrument is running on batteries, however, this step may be postponed until later to preserve battery power.) The microscope would automatically get itself as ready as possible for imaging, for example ramping the filament to a temperature at which its lifetime is not shortened, but it remains near enough to the operating temperature that normal operation can be achieved relatively quickly without any stress to the filament. At this point the user could start the tablet computer, smartphone, or other consumer device, or even visit a website, at which point the microscope is automatically turned on fully (if running under batteries, this could be the point at which it performs the previous steps mentioned, having postponed preparation of the microscope for imaging until needed to preserve battery life).

Once the user has indicated that the imaging session is over, which could be either via a preprogrammed time limit, period of inaction or by closing an application, leaving a website, putting a device to sleep, or a suitable alternative method, the microscope returns to a “ready” state where the filament longevity is not reduced but the microscope is ready to start at a moment's notice. An example of the “ready” state may include leaving the high voltage energized and stable while turning the filament to a reduced current level to protect its longevity. If running under battery power, the microscope may skip this state and return to its minimum power state as soon as possible.

At some other point the microscope could enter its power off state, if for example an off button was pushed or an option in the software selected or some other indication that the microscope needed to power down. This could even be having the mains power removed from the microscope. At this point the microscope would safely shutdown any remaining components.

Sequential insertion, imaging, and removal of samples 20 in the observation section may be substantially or completely automated. An automated sample-feeder may be provided to deliver samples to, and/or remove samples from imaging area 430 of the apparatus. For example, the automated sample-feeder may transfer the samples between the interior of vacuum chamber 420 and an external storage unit. The automated sample-feeder may additionally or alternatively include a track or belt conveyor for moving cartridge 400 from interior of airlock 440 to anchor 485. The storage section of the automated sample-feeder may store samples that are not currently being analyzed. For example, the storage unit may include a magazine for storing an array of sample sticks 90.

For example, the controller may control transfer arm 500 as well as components of the microscope. The controller may execute a custom process, which may be made up of smaller sub-processes. These sub-processes may include, for example, monitoring the automated sample-feeder and the apparatus, performing other actions at certain times and/or conditions, interacting with other external and/or internal processes (e.g., starting, stopping, or checking statuses), and changing properties in the apparatus (e.g., sending a command to another system, setting a voltage on a TTL or CMOS signal, sending a response to a request, setting an event). Multiple processes may be combined into one, and any individual process may itself be composed of smaller processes.

As processes are executed, the controller may monitor them to gauge the status (or “health”) of the microscope system. For example, the measurements can be evaluated periodically to determine whether system performance is varying over long and short timescales. Processes may be monitored in many ways, including determining how long the processes take, what outputs they produce, and what inputs they are given. The results of the process monitoring can be presented in simple, concise fashion (e.g., accessible graphs on website, raw text files, or log files). Regular reports from the system monitoring can be automatically prepared and distributed. For example, such reports could be published on website, or emailed to specified parties.

Limits can be defined at the controller for acceptable values for any monitored variable. If the acceptable range is exceeded, reports detailing the event can be automatically distributed (e.g., website, email, text message, or log message). Reports can be sent immediately or else at specified intervals with a summary of all reports during that interval.

The health monitoring process can perform actions such as (i) checking whether the pressure in the analysis section of the microscope is within sensible limits, and (ii) checking whether the tape tension is within acceptable limits. If any of these, or other, values are outside predetermined limits, actions such as notifying users (either directly/email etc.), logging to a file or emailing a set of addresses can be performed.

Using the framework described above it is possible for processes to interact with internal and external systems in a very connected way. For example, it is possible to add actions at any stage in a process that set a TTL pin low or high (or send data on a port, set a global event, etc.). This could be used to synchronize processes with an external system, for example a camera exposure triggering system. In this manner complex procedures can occur in parallel synchronized with each other.

As discussed above, an aspect of automation is computer control of the physical or image-forming elements of the microscope system. This can include computer control of the lenses, deflectors, and other components, of the microscope to put the microscope in a known state, such as a good imaging state. For example, a detector may be treated as a computer-controlled subsystem of microscope. The computer may also control the stage to position and/or tilt the sample.

A charged-particle beam microscope (such as an electron microscope) may be able, in one example, to update in response to human inputs on at greatest the order of about 0.5 Hz (or even about 1 Hz). A typical human response time may be around 500 ms. In other words, the controller should be able to execute controls and commands and provide (e.g., indicators and states) on a certain desirable timescale, such as, for example, the order of about 1 Hz (i.e., 1 second) or less. Based on human inputs or computer instructions, the microscope controller may issue automated or procedural commands to achieve certain objectives. These commands may include variants of control sets that automate certain activities that a human operator may have performed on a conventional charged-particle-beam microscope as well as tasks that a human would not have conventionally performed. These tasks may include, for example, highly repetitive actions or precise actions or myriad actions (e.g., adjusting multiple controls simultaneously (in concert)).

Controller commands can be strung together into procedures. Examples of such controller commands include (1) focusing/tuning an image, (2) moving the stage (i.e., sample location) from location to location in a controlled precise way or even a controlled random way, (3) and steering and/or shaping the beam using a single control or multiple controls (e.g., beam shaping controls, focusing controls).

This computerization and automation transforms the microscope from a static system to a dynamic system. Through digitization, we turn the microscope into a discrete “time-slice” machine. We can extend the dynamicity to a small plurality of different areas on the same sample, and we can extend the dynamicity to a large plurality of different areas on the same sample.

For example, we can use a large, high-density pixel sensor in the case of TEM (e.g., collecting 10 μm image(s) on the sample, corresponding to a few thousand times magnification with the microscope). We can increase areal coverage by increasing sensor density and through parallelization. The areal coverage may be expanded to be, for example, on the order of several mm² per sample.

If the sample can be provided with increased areal extent, the microscope system in general can expand to that size with sufficient detector speed (e.g., 10 s-100 s of sample locations per second). The digitization of controls of the microscope (e.g., optical system, sample positioning system) can be used to do this.

In terms of areal coverage of a single sample, conventional images have been captured that are composed of 10-100 sub-images in montages and microscopes have been automated to do the same. But we may be able to do 10,000 images or more, with each image being, for example, about 10 μm in field size (e.g., width dimension) with a high-density pixel detector.

The systems described above can provide the ability to exchange samples in an automated way. For example, an automated sample feeder may transfer a sample at least every 3 to 4 seconds. The automated sample feeder may do so with great precision and with the ability to uniquely identify each sample with a barcode or RFID tag. For example, the automated sample feeder may be able to identify each sample with an error less than 1 out of 10,000. “Error” in this context can refer to mismovement or misidentification of the sample.

Since robustness and safety of the microscope system is provided, it is low cost and virtually effortless for the controller to control the microscope to retry sample exchange (e.g., reattempt the insertion or exchange of a target sample) and correctly identify the sample with vanishingly low error.

Further, with the ability to capture massive areas of the sample, the microscope can execute artificial intelligence algorithms to analyze the image data. For example, the controller may measure the product of a manufacturing process in which multiple variables were varied across the sample rapidly and efficiently (e.g., combinatorial chemistry). In other examples, the microscope may image and process the images of sequentially related samples from one body (3D tissue volume reconstruction, biopsy, pathology).

The microscope computer can use AI algorithms to efficiently produce quantitative or at least qualitative data supporting the conversion of physical arrangements of objects or properties of objects into quantifiable values that can be used for decision-making. These may be used, for example, for blood cell counting, identification of pollutants, concentration of pollutants, or evaluation of purity. This AI pipeline may lend itself well to AI algorithms that have a specific, objective function.

AI identification algorithms may include, for example, adversarial networks or a training data set using human-identified components. The microscope computer may implement different types of image processing to identify, for example, counts or morphology. For example, for identification of asbestos the controller may search for long and thin shapes. In that example, the sample may preferably be imaged on a background that is uniform or predictable.

Systems and elements described above may be integrated to produce a complete automated system (“pipeline”). For example, computer or digital control, rapid and reproducible sample exchange, automation of sample exchange, and artificial intelligence algorithms may be integrated into a pipeline. The pipeline may be implemented using various considerations and tradeoffs. For example, the pipeline may be implemented with “impedance-matching” (e.g., avoiding throughput bottlenecks that create inefficiencies) and/or other synergies between the elements.

For example, the pipeline can start with myriad samples that have been prepared in an automated manner and those samples can be placed in one of various types of medium carriers (e.g., sample sticks). The sample media containing the samples go into the microscope, the microscope does automated imaging, and the microscope generates numerous images. The microscope may or may not store the images for future use.

It may be highly advantageous to simultaneously pipeline the analysis portion of the workflow. This can reduce the latency to decision and valuable information. A number of examples are provided:

Example 1: A “subtiler” montages the subtiles (sub-images) and produces information that makes it easier to do the master montage of the (montage) image later.

Example 2: The controller performs image processing to search for and identify a particular type of particle. In one embodiment, to reduce storage or processing needs, any image that does not contain that particle type may be discarded.

For example, it may be valuable to balance the storage of the data with the synthesis of the data to reduce latency of the result and enhance efficiency. It may be valuable to balance archival needs (e.g., for regulatory proof) against future needs like processing time or against financial cost.

Live-processing vs batch-processing. These respective modes may be suitable in different use cases. But batch processing usually has higher latency.

All elements in the pipeline may be “impedance-matched” such that the sample processing rate through the system is maximized. For example, it may be advantageous to include suitable buffers in sequential stages to ensure no single element is waiting too long for the next or previous step.

Unifying documentation. Samples may benefit from a traveling/following document. This may take the form of a software data structure that includes metadata about the current process and historical treatments. This data structure may also include snapshots of results from each step of the pipeline, which can aid in tracking and ensuring quality of the result.

At a higher level, a plurality of such pipelines may in turn be integrated into a larger pipeline. Each of these plurality of pipelines may optimized for a specific purpose. For example, the sample delivery automation process, the AI process, etc. can be configured to a specific application. This lends itself to parallelizability. The considerations and tradeoffs discussed above (e.g., reducing costs, storage, image-processing times) may again apply at this higher level.

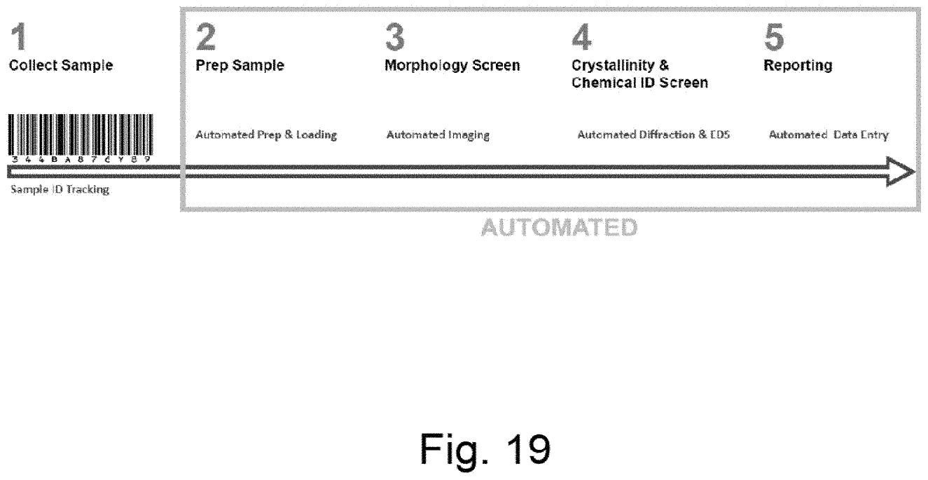

FIG. 19 is an example of an embodiment of a workflow in an automated sample preparation, delivery, charged-particle-beam imaging, and analysis pipeline.

Further, charged-particle-beam microscopes can be configured in an ensemble containing a plurality of charged-particle-beam microscopes that operate in concert to process a large batch of samples. For example, all of the charged-particle-beam microscopes in an ensemble may be controlled from a single portable device having a UI, or in parallel from multiple portable devices. The portable device and/or the controllers of the microscopes may communicate with each other to coordinate the operations of the microscopes in the ensemble.

Although the foregoing embodiments have been described in detail by way of illustration and example for purposes of clarity of understanding, it will be readily apparent to those of ordinary skill in the art in light of the description herein that certain changes and modifications may be made thereto without departing from the spirit or scope of the appended claims. It is also to be understood that the terminology used herein is for the purpose of describing particular aspects only, and is not intended to be limiting, since the scope of the present invention will be limited only by the appended claims.

It is noted that, as used herein and in the appended claims, the singular forms “a”, “an”, and “the” include plural referents unless the context clearly dictates otherwise. It is further noted that the claims may be drafted to exclude any optional element. As such, this statement is intended to serve as antecedent basis for use of such exclusive terminology as “solely,” “only,” and the like in connection with the recitation of claim elements, or use of a “negative” limitation. As will be apparent to those of ordinary skill in the art upon reading this disclosure, each of the individual aspects described and illustrated herein has discrete components and features which may be readily separated from or combined with the features of any of the other several aspects without departing from the scope or spirit of the disclosure. Any recited method can be carried out in the order of events recited or in any other order which is logically possible. Accordingly, the preceding merely provides illustrative examples. It will be appreciated that those of ordinary skill in the art will be able to devise various arrangements which, although not explicitly described or shown herein, embody the principles of the disclosure and are included within its spirit and scope.

Furthermore, all examples and conditional language recited herein are principally intended to aid the reader in understanding the principles of the invention and the concepts contributed by the inventors to furthering the art, and are to be construed without limitation to such specifically recited examples and conditions. Moreover, all statements herein reciting principles and aspects of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary configurations shown and described herein.

In this specification, various preferred embodiments have been described with reference to the accompanying drawings. It will be apparent, however, that various other modifications and changes may be made thereto and additional embodiments may be implemented without departing from the broader scope of the claims that follow. The specification and drawings are accordingly to be regarded in an illustrative rather than restrictive sense.

We claim:

1. A charged-particle-beam microscope for imaging a sample, the microscope comprising:
a stage to hold a sample;
an automated sample feeder to repeatedly and automatically exchange the sample from among a plurality of samples;
a charged-particle-beam column to direct a charged-particle-beam onto the sample, the charged-particle-beam column comprising:
a charged-particle-beam source to generate an electron beam, and
charged-particle-beam optics to converge the charged-particle beam onto the sample, and
a detector to detect charged particles emanating from the sample to generate image data; and
a controller to analyze the image data to generate an image, the controller being adapted to execute an artificial intelligence algorithm to analyze the image.

2. The charged-particle-beam microscope of claim 1, wherein the charged-particle-beam column further comprises a beam scanner to scan the charged-particle beam across the sample.

3. The charged-particle-beam microscope of claim 1, wherein the charged-particle-beam microscope is a transmission electron microscope (TEM).

4. The charged-particle-beam microscope of claim 1, wherein the automated sample feeder comprises a magazine having a plurality of sample sticks.

5. The charged-particle-beam microscope of claim 1, wherein the automated sample feeder comprises a grid tape loader.
